(19) United States
(12) Patent Application Publication
(10) Pub. No.: US 2024/0315060 A1
(43) Pub. Date: Sep. 19, 2024

(54) PHOTOELECTRIC CONVERSION DEVICE AND IMAGE SENSOR INCLUDING THE SAME

(71) Applicant: Samsung Electronics Co., Ltd., Suwon-si (KR)

(72) Inventors: Byeongeun KWAK, Suwon-si (KR); Joon Hak OH, Seoul-si (KR); Kiryong LEE, Suwon-si (KR); Sang Hyuk LEE, Seoul-si (KR); Moon-Ki JEONG, Seoul-si (KR); Seungwon KIM, Suwon-si (KR); Songse YI, Suwon-si (KR); Yeseul LEE, Suwon-si (KR); Joowon LEE, Suwon-si (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 18/593,261

(22) Filed: Mar. 1, 2024

(30) Foreign Application Priority Data
Mar. 14, 2023 (KR) 10-2023-0033478

(51) Int. Cl. H10K 30/20; H10K 30/85; H10K 30/86; H10K 30/87; H10K 39/32; H10K 39/38; H10K 85/10; H10K 85/20; H10K 85/30; H10K 85/60; H10K 101/30; H10K 101/40

(52) U.S. Cl. CPC H10K 30/20; H10K 30/85; H10K 30/86; H10K 30/87; H10K 39/32; H10K 39/38; H10K 85/113; H10K 85/215; H10K 85/331; H10K 85/381; H10K 85/655; H10K 85/6572; H10K 85/6576; H10K 2101/30; H10K 2101/40

(57) ABSTRACT

A photoelectric conversion device according to some example embodiments includes an upper electrode, a lower electrode, and an active layer including a donor material, an acceptor material, and a light-absorbing material and disposed between the upper electrode and the lower electrode, wherein the donor material includes a compound represented by Formula 1, and the light-absorbing material includes bis-(4-dimethylaminodithiobenzyl)-Ni(II) (BDN).

### CROSS-REFERENCE TO RELATED APPLICATION

This application is based on and claims priority under 35 U.S.C. § 119 to Korean Patent Application No. 10-2023-0033478, filed on Mar. 14, 2023, in the Korean Intellectual Property Office, the disclosure of which is incorporated by reference herein in its entirety.

### BACKGROUND

The present disclosure relates to photoelectric conversion devices and image sensors including the same. More particularly, the present disclosure relates a short wave infrared (SWIR) photoelectric conversion devices and image sensors including the same.

The short wave infrared (SWIR) has a wavelength in a range of about 1 μm to about 3 μm. Image sensors including a SWIR photoelectric conversion device may be used for various applications, such as environmental pollution, surveillance, bio-imaging, medical, agriculture, food, and automotive. Silicon does not absorb SWIR and is thus not suitable for SWIR sensing. Currently, there is a limitation in that image sensors including InGaAs-based SWIR photoelectric conversion devices are expensive. Therefore, there is a need to develop low-cost SWIR photoelectric conversion devices and image sensors including the same.

### SUMMARY

Some aspects of the present disclosure provide SWIR photoelectric conversion devices and image sensors including the same.

According to some example embodiments of the inventive concepts, a photoelectric conversion device is provided. The photoelectric conversion device may include an upper electrode; a lower electrode; and an active layer including a donor material, an acceptor material, and a light-absorbing material, the active layer between the upper electrode and the lower electrode, the donor material including a compound represented by Formula 1 below, and the light-absorbing material including bis-(4-dimethylaminodithiobenzyl)-Ni (II) (BDN).

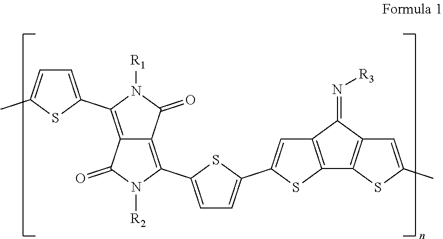

wherein in Formula 1, R₁ and R₂ are each independently a hydrogen atom, a C1 to C30 linear alkyl group that is unsubstituted or substituted with a substituent, or a C3 to C20 branched alkyl group that is unsubstituted or substituted with a substituent, R₃ is a hydrogen atom, a C6 to C30 aryl group that is unsubstituted or substituted with a substituent, or a C3 to C30 heteroaryl group that is unsubstituted or substituted with a substituent, and n is an integer between 20 and 100,000.

According to some example embodiments of the inventive concepts, a photoelectric conversion device is provided. The photoelectric conversion device may include an upper electrode; a lower electrode, and an active layer including a donor material, an acceptor material, and a light-absorbing material and disposed between the upper electrode and the lower electrode, wherein the light-absorbing material includes a compound represented by Formula 2-1, an absolute value of a difference between a highest occupied molecular orbital (HOMO) energy level of the donor material and a HOMO energy level of the light-absorbing material is 0.2 eV or less.

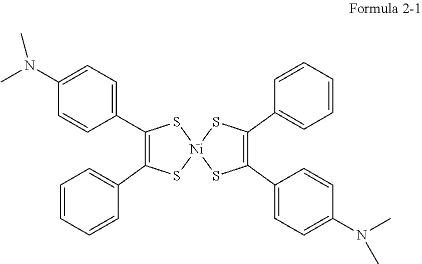

According to some example embodiments of the inventive concepts, provided is an image sensor. The image sensor may include a semiconductor substrate; a charge storage in the semiconductor substrate; an insulating layer on the semiconductor substrate; a photoelectric conversion device on the insulating layer; and a wiring connecting the photoelectric conversion device and the charge storage, wherein the photoelectric conversion device includes a lower electrode connecting to the wiring, an active layer on the lower electrode, and an upper electrode on the active layer, the active layer includes a donor material, an acceptor material, and a light-absorbing material, the donor material includes a compound represented by Formula 1 below, and the light-absorbing material includes a compound represented by Formula 2-1 below.

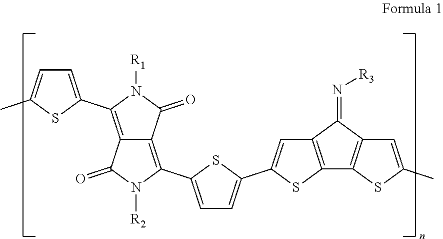

wherein in Formula 1, R₁ and R₂ are each independently a hydrogen atom, a C1 to C30 linear alkyl group that is unsubstituted or substituted with a substituent, or a C3 to C20 branched alkyl group that is unsubstituted or substituted with a substituent, R₃ is a hydrogen atom, a C6 to C30 aryl group that is unsubstituted or substituted with a substituent, or a C3 to C30 heteroaryl group that is unsubstituted or substituted with a substituent, and n is an integer between 20 and 100,000.

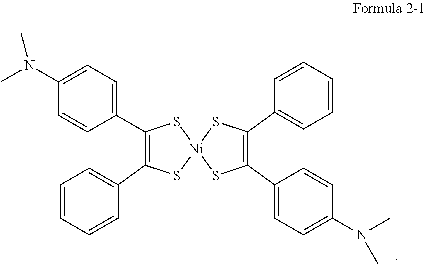

### BRIEF DESCRIPTION OF THE DRAWINGS

Example embodiments will be more clearly understood from the following detailed description taken in conjunction with the accompanying drawings in which:

FIG. 1 is a cross-sectional view illustrating a photoelectric conversion device according to some example embodiments;

FIG. 2 is a diagram illustrating a highest occupied molecular orbital (HOMO) energy level and a lowest unoccupied molecular orbital (LUMO) energy level of a donor material, a HOMO energy level and a LUMO energy level of a light-absorbing material, and a HOMO energy level and a LUMO energy level of an acceptor material, according to some example embodiments;

FIG. 3 is a cross-sectional view illustrating a photoelectric conversion device according to some example embodiments;

FIG. 4 is a cross-sectional view illustrating an image sensor according to some example embodiments;

FIG. 5 is a cross-sectional view illustrating an image sensor according to some example embodiments;

FIG. 6 is a light absorption spectrum of bulk hetero junction (BHJ) films according to Example 1 and Comparative Examples 1 to 3; and

FIG. 7 is a time-photocurrent graph of a photoelectric conversion device for light of 1300 nm, 5 μW cm⁻², according to Preparation Example 1.

### DETAILED DESCRIPTION

Hereinafter, the present inventions will be explained in detail with reference to the accompanying drawings. Like drawing reference numerals are used for like elements, and duplicate descriptions thereof will be omitted.

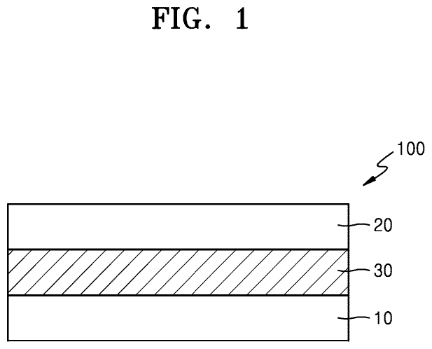

FIG. 1 is a cross-sectional view illustrating a photoelectric conversion device 100 according to some example embodiments of the inventive concepts.

Referring to FIG. 1, the photoelectric conversion device 100 may include a lower electrode 10, an upper electrode 20, and an active layer 30 disposed between the lower electrode 10 and the upper electrode 20. For example, the photoelectric conversion device 100 may include the lower electrode 10, the active layer 30, and the upper electrode 20, which are sequentially stacked.

According to some example embodiments, at least one of the lower electrode 10 or the upper electrode 20 may be a transparent electrode capable of transmitting short wave infrared (SWIR) light. For example, the lower electrode 10 and the upper electrode 20 may each include indium tin oxide (ITO), indium zinc oxide (IZO), aluminum doped zinc oxide (AZO), fluorine doped tin oxide (FTO), tin oxide (SnO₂), titanium oxide (TiO₂), zinc oxide (ZnO), calcium (Ca), gold (Ag), silver (Ag), aluminum (Al), titanium (Ti), a doped polysilicon, graphene, a carbon nanotube (CNT), or a combination thereof.

According to some example embodiments, the active layer 30 may include a donor material, an acceptor material, and a light-absorbing material. In some example embodiments, the active layer 30 may have a structure in which the donor material, the acceptor material, and the light-absorbing material are randomly mixed and disposed in the active layer 30 regardless of a vertical and/or horizontal position. For example, the active layer 30 may have a bulk hetero junction (BHJ) structure. In some example embodiments, the active layer 30 may include a plurality of material layers disposed at different levels in a vertical direction. In this case, the plurality of material layers may each be independently formed from the donor material, the acceptor material, or the light-absorbing material, and stacked orders and number of stacks of each material are not limited.

According to some example embodiments, the donor material may include a conjugated polymer including a donor moiety and an acceptor moiety in a repeating unit. In some example embodiments, the donor moiety and the acceptor moiety may be alternately linked to each other.

According to some example embodiments, the donor material may include a compound represented by Formula 1 below.

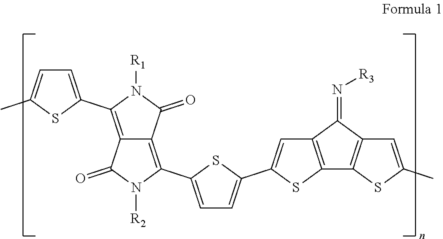

where, in Formula 1, R₁ and R₂ may each independently be a hydrogen atom, a C1 to C30 linear alkyl group that is unsubstituted or substituted with a substituent, or a C3 to C20 branched alkyl group that is unsubstituted or substituted with a substituent. The substituent may include a C6 to C20 aryl group, a C3 to C20 heteroaryl group, a C7 to C30 arylalkoxy group, a C7 to C20 acyloxy group, a thiol group, a hetero atom, a halogen atom. The C3 to C20 heteroaryl group may include a C4 to C20 thiophenyl group, a C4 to C20 pyrrolyl group, a C5 to C20 pyridinyl group, a C4 to C20 pyrimidinyl group. The hetero atom may include a nitrogen atom, an oxygen atom, or a sulfur atom, but is not limited thereto.

In Formula 1, R₃ may be a hydrogen atom, a C6 to C30 aryl group that is unsubstituted or substituted with a substituent, or a C3 to C30 heteroaryl group that is unsubstituted or substituted with a substituent. The substituent may include a C3 to C20 linear alkyl group, or a C3 to C20 branched alkyl group, a C1 to C20 acyl group, a C1 to C20 carboxylate group, a hetero atom, or a halogen atom. The hetero atom may include a nitrogen atom, an oxygen atom, or a sulfur atom, but is not limited thereto. Further, wherein, in Formula 1, n may be an integer between 20 and 100,000. R₃ may be an aryl group or heteroaryl group, connected to a nitrogen atom, and thus may improve the electrical stability of the conjugated polymer along with a thiophene linker. Consequently, the HOMO level of the donor material may be increased and the band gap of the donor material may be reduced.

In some example embodiments, the compound represented by Formula 1 may have a structure in which a donor moiety (e.g. a cyclopentadithiophene (CPDT) moiety) and an acceptor moiety (e.g. a diketopyrrolopyrrol (DPP) moiety) are alternately linked to each other via a thiophene linker. The planarity of the donor material may be improved due to an interaction of a sulfur atom of thiophene, an oxygen atom and nitrogen atom of DPP, and a sulfur atom and a nitrogen atom of CPDT such that performance of a photoelectric conversion device 100 may be improved due to the planarity of the donor material.

In some example embodiments, the donor material may include a compound represented by Formula 1-1 below.

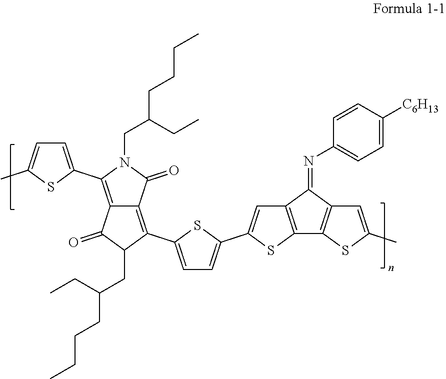

wherein, in Formula 1-1, n may be an integer between 20 and 100,000.

According to some example embodiments, the light-absorbing material may include bis-(4-dimethylaminodithiobenzyl)-Ni(II) (BDN) represented by Formula 2-1 below.

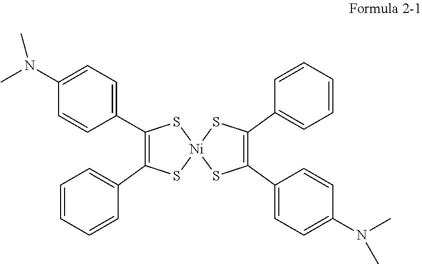

In some example embodiments, the light-absorbing material may include a compound represented by Formula 2-2 below.

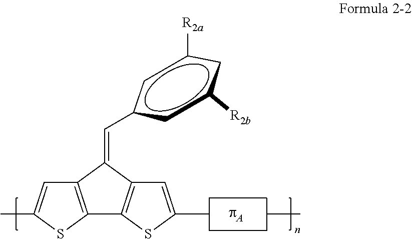

where, in Formula 2-2, R₂ₐ and R_{2b} may each independently be a hydrogen atom, a C1 to C20 linear alkyl group that is unsubstituted or substituted with a substituent, a C3 to C20 branched alkyl group that is unsubstituted or substituted with a substituent, a C6 to C30 aryl group that is unsubstituted or substituted with a substituent, or a C3 to C30 heteroaryl group that is unsubstituted or substituted with a substituent. The substituent may include a C1 to C20 acyl group, a C1 to C20 carboxylate group, a hetero atom, or a halogen atom. The hetero atom may include a nitrogen atom, an oxygen atom, or a sulfur atom, but is not limited thereto.

In Formula 2-2, π_{A} may be one selected from Formulas 3-1, 3-2, and 3-3 below, and n may be an integer of 20 to 10,000.

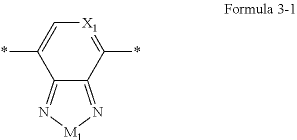

where, in Formula 3-1, X₁ may be a carbon atom or a nitrogen atom, and M₁ may be a sulfur atom or a selenium atom. * is a bonding site for a neighboring atom.

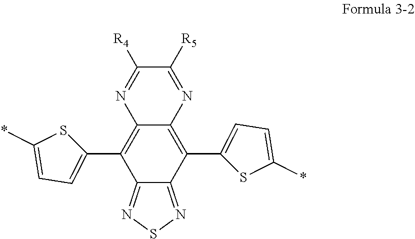

where, in Formula 3-2, R₄ and R₅ may each independently be a hydrogen atom, a C1 to C20 hydrocarbon group. For example, R₄ and R₅ may each independently be a C1 to C20 linear alkyl group, or a C3 to C20 branched alkyl group. * is a bonding site for a neighboring atom.

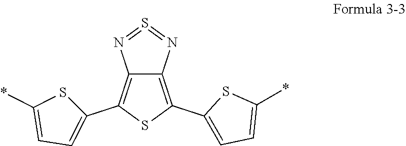 [SMILES: *c1ccc(-c2sc(-c3ccc(*)s3)c3c2N=S=N3)s1]

where, in Formula 3-3, * is a bonding site for a neighboring atom.

In some example embodiments, the light-absorbing material may include a compound represented by Formula 2-3 below.

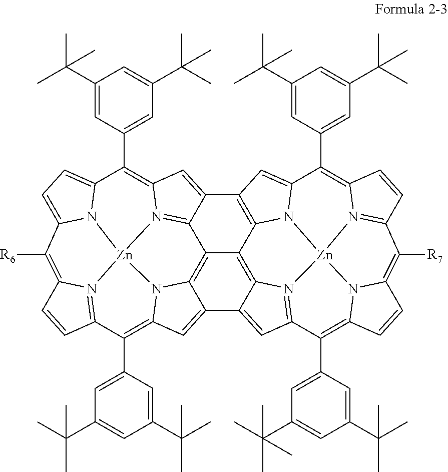

where, in Formula 2-3, R₆ and R₇ may each independently be a C6 to C30 aryl group that is unsubstituted or substituted with a substituent, or a C3 to C30 heteroaryl group that is unsubstituted or substituted with a substituent. The substituent may include a C1 to C20 linear or branched alkyl group, a hydroxy group, a carboxyl group, an amino group, a nitro group, a cyano group, an isocyanate group, a thiol group, a sulfonic acid group, a phosphoric acid group or salts thereof. The hetero atom may include a nitrogen atom, an oxygen atom, or a sulfur atom, but is not limited thereto.

In some example embodiments, R₆ and R₇ in Formula 2-3 may each independently be selected from Formulas 4-1, 4-2, and 4-3 below.

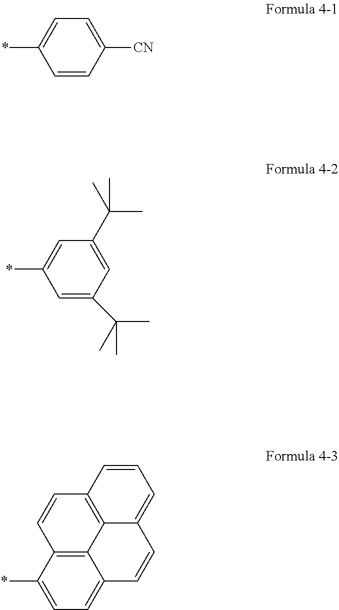 [SMILES: *c1ccc(C#N)cc1 ; *c1cc(C(C)(C)C)cc(C(C)(C)C)c1 ; *c1ccc2ccc3cccc4ccc1c2c34]

where, in Formulas 4-1 to 4-3, * is a bonding site for a neighboring atom.

In some example embodiments, the light-absorbing material may include a compound represented by Formula 2-4.

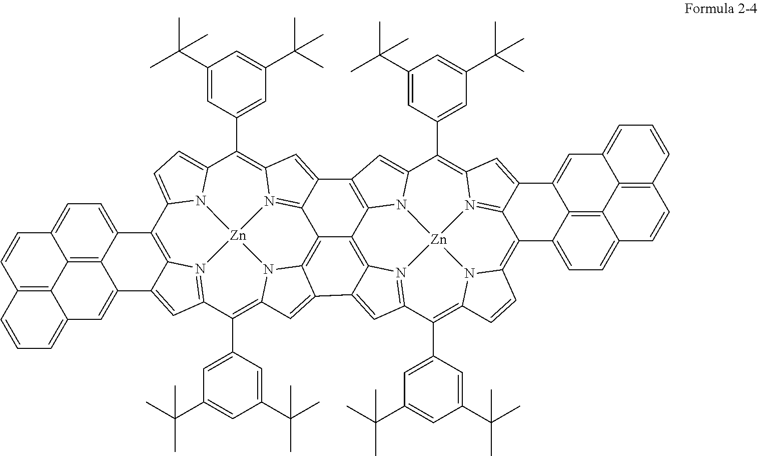

According to some example embodiments, the acceptor material may include [6,6]-phenyl-C71-butyric acid methyl ester (PC₇₀BM), [6,6]-phenyl-C61-butyric acid methyl ester (PC₆₀BM), bis(1-[3-(methoxycarbonyl)propyl]-1-phenyl)-[6,6]C62 (Bis-PCBM), poly{[N,N-bis(2-octyldodecyl)-naphthalene-1,4,5,8-bis(dicarboximide)-2,6-diyl]-alt-5,5-(2,29-bisthiophene)} (N2200), perylene diimide (PDI), or naphthalene diimide (NDI).

For example, PC₇₀BM may be represented by Formula 5-1.

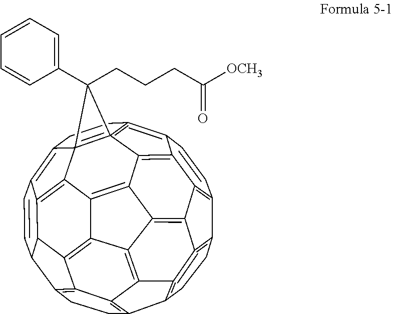

For example, bis-PCBM may be represented by Formula 5-2.

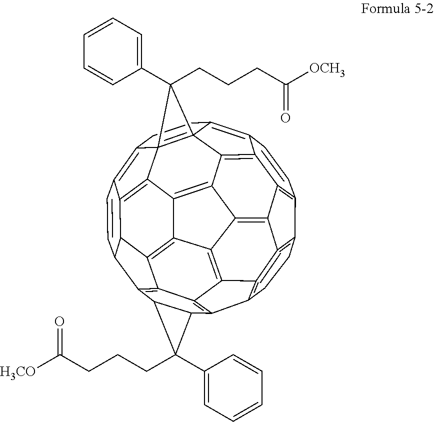

For example. N2200 may be represented by Formula 5-3.

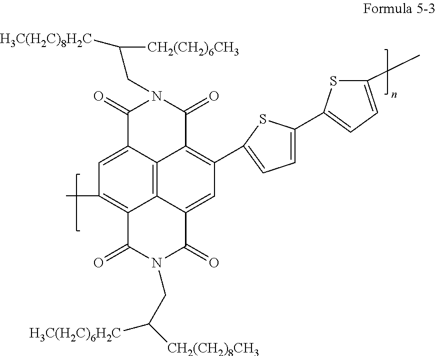

For example, PDI may be represented by Formula 5-4.

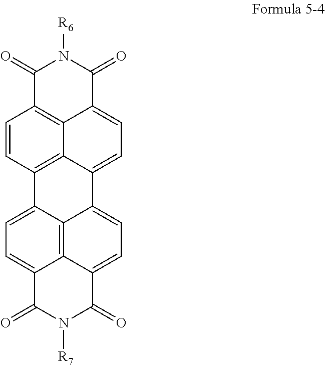

where, in Formula 5-4, R₆ and R₇ may each independently be a hydrogen atom, a C1 to C20 linear alkyl group that is unsubstituted or substituted with a substituent, a C3 to C20 branched alkyl group that is unsubstituted or substituted with a substituent, a C6 to C30 aryl group that is unsubstituted or substituted with a substituent, or a C3 to C30 heteroaryl group that is unsubstituted or substituted with a substituent. The substituent may include a C1 to C20 acyl group, a C1 to C20 carboxylate group, a hetero atom, or a halogen atom. The hetero atom may include a nitrogen atom, an oxygen atom, or a sulfur atom, but is not limited thereto.

For example, NDI may be represented by Formula 5-5.

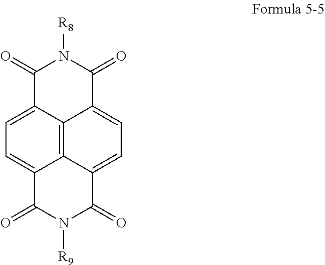

where, in Formula 5-5, R₈ and R₉ may each independently be a hydrogen atom, a C1 to C20 linear alkyl group that is unsubstituted or substituted with a substituent, a C3 to C20 branched alkyl group that is unsubstituted or substituted with a substituent, a C6 to C30 aryl group that is unsubstituted or substituted with a substituent, or a C3 to C30 heteroaryl group that is unsubstituted or substituted with a substituent. The substituent may include a C1 to C20 acyl group, a C1 to C20 carboxylate group, a hetero atom, or a halogen atom. The hetero atom may include a nitrogen atom, an oxygen atom, or a sulfur atom, but is not limited thereto.

For example, NDI may be represented by Formula 5-6.

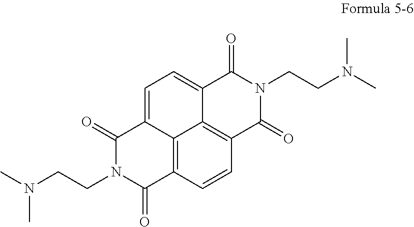

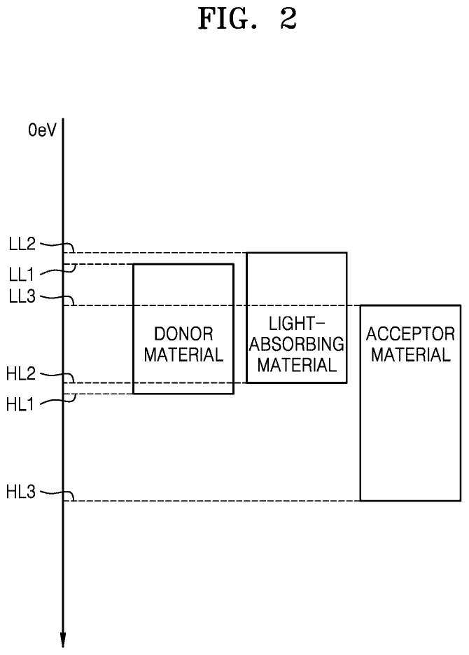

FIG. 2 is a diagram illustrating a first highest occupied molecular orbital (HOMO) level HL1, which is a HOMO energy level of the donor material, and a first lowest unoccupied molecular orbital (LUMO) level LL1, which is a LUMO energy level of the donor material, a second HOMO level HL2, which is a HOMO energy level of the light-absorbing material, and a second LUMO level LL2, which is a LUMO energy level of the light-absorbing material, and a third HOMO level HL3, which is a HOMO energy level of the acceptor material, and a third LUMO level LL3, which is a LUMO energy level of the acceptor material, in the photoelectric conversion device 100 according to some example embodiments of the inventive concepts.

Each of HOMO levels HL1, HL2, and HL3 and LUMO levels LL1, LL2, and LL3 of the donor material, the light-absorbing material, and the acceptor material are values calculated by using cyclic voltammetry (CV) data measured by using the lviumStat.h equipment, and are negative values.

Referring to FIG. 2, the first LUMO level LL1 of the donor material may be less than the second LUMO level LL2 of the light-absorbing material. In some example embodiments, the first LUMO level LL1 of the donor material may be greater than the second LUMO level LL2 of the light-absorbing material. According to some example embodiments, the first HOMO level HL1 of the donor material may be less than the second HOMO level HL2 of the light-absorbing material. In some example embodiments, the first HOMO level HL1 of the donor material may be greater than the second HOMO level HL2 of the light-absorbing material.

In some example embodiments, the first HOMO level HL1 of the donor material may be about or exactly −5.1 eV or more. For example, the first HOMO level HL1 of the donor material may be about or exactly −5.1 eV to about or exactly −4.8 eV. For example, the first HOMO level HL1 of the donor material may be about or exactly −5.0 eV to about or exactly −4.9 eV.

In some example embodiments, the second HOMO level HL2 of the light-absorbing material may be about or exactly −5.2 eV or more. For example, the second HOMO level HL2 of the light-absorbing material may be about or exactly −5.2 eV to about or exactly −4.6 eV. For example, the second HOMO level HL2 of the light-absorbing material may be about or exactly −4.9 eV to about or exactly −4.7 eV.

According to some example embodiments, an absolute value of a difference between the first HOMO level HL1 of the donor material and the second HOMO level HL2 of the light-absorbing material may be about or exactly 0.3 eV or less. In some example embodiments, the absolute value of a difference between the first HOMO level HL1 of the donor material and the second HOMO level HL2 of the light-absorbing material may be about or exactly 0.25 eV or less, about or exactly 0.2 eV or less, or about or exactly 0.15 eV or less.

In some example embodiments, the absolute value of a difference between the first LUMO level LL1 of the donor material and the second LUMO level LL2 of the light-absorbing material may be about or exactly 0.3 eV or less. In some example embodiments, the absolute value of a difference between the first LUMO level LL1 of the donor material and the second LUMO level LL2 of the light-absorbing material may be about or exactly 0.25 e V or less, about or exactly 0.2 eV or less, or about or exactly 0.13 eV or less.

According to some example embodiments, a band gap energy of the donor material may be about or exactly 1.5 eV or less. For example, the band gap energy may be calculated as the absolute value of the difference between a HOMO level and a LUMO level. In some example embodiments, the band gap energy of the donor material may be about or exactly 1.4 eV or less, about or exactly 1.35 eV or less, or about or exactly 1.3 eV or less.

In the active layer 30 of the photoelectric conversion device 100 according to some example embodiments, a difference of HOMO levels between the donor material and the light-absorbing material may be about or exactly 0.3 eV or less, and the band gap energy of the donor material may be about or exactly 1.5 eV or less. Accordingly, since the hole mobility of an exciton generated in the active layer 30 including the donor material, the light-absorbing material, and the acceptor material, is improved, the reliability of the photoelectric conversion device 100 may be improved, and thus the SWIR region sensitivity of the photoelectric conversion device 100 may be improved. As described herein, an apparatus and/or device may have improved reliability, sensor clarity, and power consumption characteristics (e.g., reduced power consumption during operation), improved operational performance and/or efficiency, based on including a semiconductor device having improved reliability and hole mobility based on the semiconductor device including the active layer 30 according to some example embodiments.

In some example embodiments, an amount of the donor material may be 10 parts by weight to 80 parts by weight with respect to the total weight of the active layer 30. An amount of the light-absorbing material may be 10 parts by weight to 80 parts by weight with respect to the total weight of the active layer 30. An amount of the acceptor material may be 10 parts by weight to 80 parts by weight with respect to the total weight of the active layer 30.

In some example embodiments, the amount of the donor material in the active layer 30 may be the same as the amount of the light-absorbing material. In some example embodiments, the amount of the donor material in the active layer 30 may be greater than the amount of the light-absorbing material. In addition, in some example embodiments, the amount of the donor material in the active layer 30 may be less than the amount of the light-absorbing material.

In some example embodiments, a ratio of the amount of the light-absorbing material to the amount of the donor material in the active layer 30 may be 2:8 to 8:2. 3:7 to 7:3. 4:6 to 6:4, or 5:5.

In some example embodiments, the donor material, the light-absorbing material, and the acceptor material may be included at a same amount ratio in the active layer 30.

In some example embodiments, the active layer 30 of the photoelectric conversion device 100 may have a thickness in a range of about or exactly 10 nm to about or exactly 1000 nm. As described herein, an apparatus and/or device may have improved reliability, sensor clarity, and power consumption characteristics (e.g., reduced power consumption during operation), improved operational performance and/or efficiency, based on including a semiconductor device having improved reliability and the thickness range based on the semiconductor device including the active layer 30 according to some example embodiments.

According to some example embodiments, a light absorption spectrum of the active layer 30 may have a peak wavelength in a range of about or exactly 1 μm to about or exactly 1.4 μm. In some example embodiments, the light absorption spectrum of the active layer 30 may have a peak wavelength in a range of about or exactly 1.1 μm to about or exactly 1.4 μm. As described herein, an apparatus and/or device may have improved reliability, sensor clarity, and power consumption characteristics (e.g., reduced power consumption during operation), improved operational performance and/or efficiency, based on including a semiconductor device having improved reliability and absorption spectrum based on the semiconductor device including the active layer 30 according to some example embodiments.

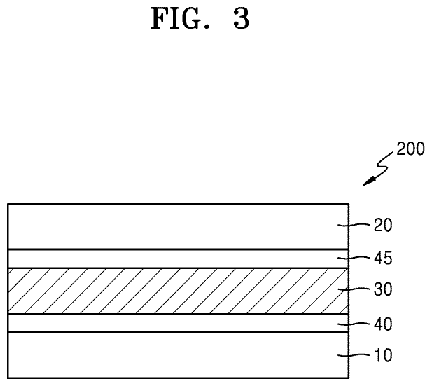

FIG. 3 is a cross-sectional view of a photoelectric conversion device 200 according to some example embodiments. The difference between FIG. 3 and FIG. 1 is whether the photoelectric conversion device 200 further includes a lower transport layer 40 between a lower electrode 10 and an active layer 30, and an upper transport layer 45 between the active layer 30 and an upper electrode 20 or not.

According to some example embodiments, the photoelectric conversion device 200 may have a structure in which the lower electrode 10, the lower transport layer 40, the active layer 30, the upper transport layer 45, and the upper electrode 20 are sequentially stacked.

In some example embodiments, the lower transport layer 40 may be a hole transport layer, and the upper transport layer 45 may be an electron transport layer. In some example embodiments, the lower transport layer 40 may be the electron transport layer, and the upper transport layer 45 may be the hole transport layer.

For example, the electron transport layer may include ZnO, TiO₂, polystyrene sulfonate (PSS), bathocuproine, or LiF. For example, the hole transport layer may include MoO₃, NiO, or Poly(3,4-ethylenedioxythiophene (PEDOT):PSS.

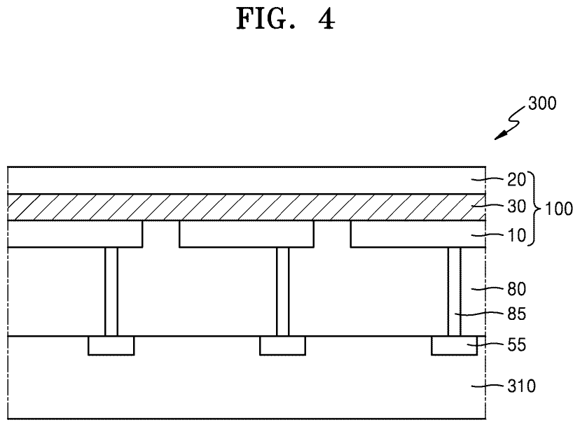

FIG. 4 is a cross-sectional view illustrating an image sensor 300 according to some example embodiments.

Referring to FIG. 4, the image sensor 300 may include a semiconductor substrate 310, a charge storage 55 in the semiconductor substrate 310, an insulating layer 80 on the semiconductor substrate 310, a photoelectric conversion device 100 on the insulating layer 80, and a wiring 85 connecting the photoelectric conversion device 100 and the charge storage 55.

According to some example embodiments, the semiconductor substrate 310 may include a semiconductor material such as a group IV semiconductor material, a group III-V semiconductor material, or a group II-VI semiconductor material. For example, the group IV semiconductor material may include silicon (Si), germanium (Ge), or silicon (Si)-germanium (Ge). For example, the group III-V semiconductor material may include gallium arsenide (GaAs), indium phosphate (InP), gallium phosphate (GaP), indium arsenide (InAs), indium antimony (InSb), or indium gallium arsenide (InGaAs). For example, the group II-VI semiconductor material may include zinc telluride (ZnTe), or cadmium sulfide (CdS).

According to some example embodiments, the charge storage 55 may be an impurity region in the semiconductor substrate 310. The charge storage 55 may also be called as a floating diffusion region. According to some example embodiments, the charge storage 55 may be connected to a transfer transistor on the semiconductor substrate 310. Photocharges generated by the photoelectric conversion device 100 may be transferred to the charge storage 55 via the wiring 85 and accumulated in the charge storage 55.

According to some example embodiments, the insulating layer 80 may include silicon oxide, silicon nitride, or a low-k dielectric material. The low-k dielectric material may include, for example, SiC, SiCOH, SiCO, SiOF, flowable oxide (FOX), tonen silazane (TOSZ), undoped silica glass (USG), borosilicate glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, acrogel, amorphous fluorinated carbon, organosilicate glass (OSG), parylene, bis-benzocyclobutenes (BCB), SILK, polyimide, a porous polymer material, or a combination thereof.

The photoelectric conversion device 100 in FIG. 4 is similar to the photoelectric conversion device described with reference to FIG. 1, but the lower electrode 10 is divided into a plurality of parts corresponding to a plurality of pixels. Light may be incident on the active layer 30 through the upper electrode 20, and the upper electrode 20 may be transparent to SWIR.

According to some example embodiments, the wiring 85 may be configured such that the plurality of divided parts of the lower electrode 10 are respectively connected to a plurality of charge storages 55. The wiring 85 may include tungsten (W), aluminum (Al), copper (Cu), silver (Ag), gold (Au), or polysilicon.

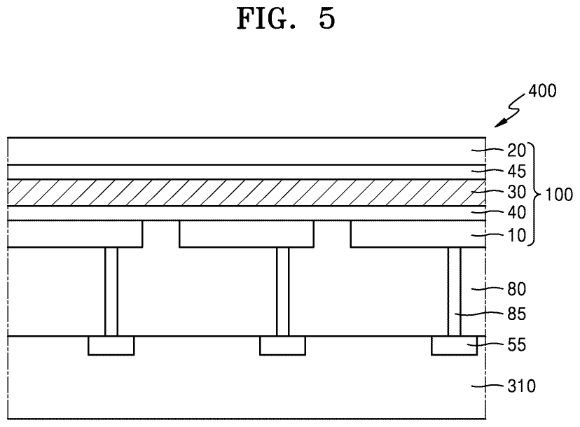

FIG. 5 is a cross-sectional view illustrating an image sensor 400 according to some example embodiments. In FIG. 5, like reference numerals in FIG. 4 refer to like members and duplicate descriptions thereof will be omitted. Hereinafter, differences between an image sensor 300 illustrated in FIG. 4, and an image sensor 400 illustrated in FIG. 5 will be mainly described.

Referring to FIG. 5, the image sensor 400 may include a photoelectric conversion device 200 instead of the photoelectric conversion device 100 illustrated in FIG. 4. The photoelectric conversion device 200 may further include a lower transport layer 40 between the lower electrode 10 and the active layer 30, and an upper transport layer 45 between the active layer 30 and the upper electrode 20. The photoelectric conversion device 200 is similar to the photoelectric conversion device 200 described with reference to FIG. 2, but the lower electrode 10 is divided into a plurality of parts.

Hereinafter, to aid in understanding the present inventive concepts, the following example embodiments are provided, including specific Examples and Comparative Examples. However, it should be noted that these Examples are merely illustrative and the present inventive concepts are not limited thereto.

### SYNTHESIS EXAMPLE

### Synthesis Example 1: Synthesis of Monomer (A-1)

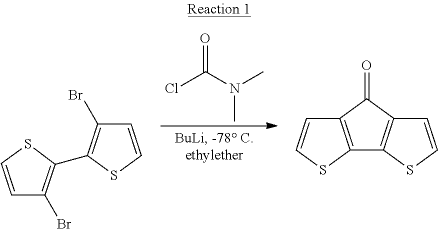

Within a 50 mL flask, 3,3′-dibromo-2,2′-bithiophene (5 g, 15.4 mmol) was dissolved in a solvent of diethyl ether (15 mL), and then temperature was lowered to −78° C. under a nitrogen condition. N-BuLi (13.6 mL, 34.0 mmol) was slowly injected at −78° C., and then the reaction was allowed for 1 hour. Then, dimethyl carbamoyl chloride (1.55 mL, 17.0 mmol) was slowly added to the mixture solution, and the resultant was stirred at room temperature overnight. After extracting a sample with diethyl ether using a separatory funnel, moisture was removed from the sample by using MgSO₄, and the resultant was filtered under reduced pressure. Then the filtrate was recrystallized to obtain an intermediate compound (a) (4H-cyclopenta[2,1-b: 3,4-b′] dithiophen-4-oene), which is a product according to Reaction 1, (yield: 42%).

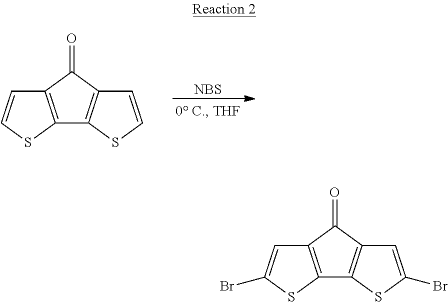

The intermediate compound (a) (0.3 g, 1.56 mmol) was dissolved in 15 mL of THF within a 50 mL two-necked flask under a nitrogen atmosphere and shading. Then the temperature of the produced solution was lowered to 0° C. NBS (0.7 mg, 3.90 mmol) was added to the solution and the mixture was stirred at 0° C. for 4 hours, and 10 ml of 10% Na₂S₂O₃ solution was injected into the formed mixture. After extracting a sample with chloroform using a separatory funnel, moisture was removed from the sample by using MgSO₄, and the resultant was filtered under reduced pressure. The filtrate was then recrystallized to obtain an intermediate compound (b) (2,6-dibromo-4H-cyclopenta[2,1-b:3,4-b′]dithiophen-4-oene), which is a product according to Reaction 2, (yield: 87%).

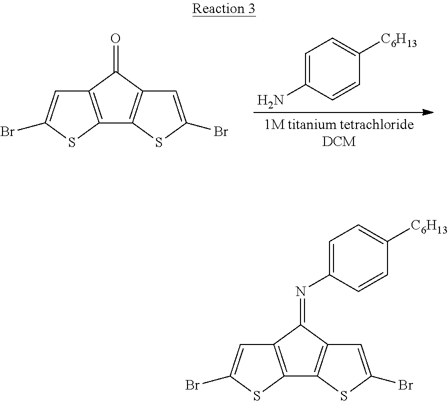

4-hexylaniline (380 mg, 2.14 mmol) and triethylamine (500 mg, 4.94 mmol) were added to 10 mL of 1,2-dichloromethane solution, and a temperature was maintained at −35° C. in an N₂ atmosphere. 1 M of titanium tetrachloride (210 mg, 1.11 mmol) was added dropwise for 5 minutes to form a deep red solution. The resultant mixture was then stirred for 5 minutes. An intermediate compound (c) (500 mg, 1.42 nmol) was cooled and added to a 5 mL of 1,2-dichloromethane solution, and the mixture was vigorously stirred to precipitate. The solution was then left at room temperature and stirred overnight. 40 mL of diethyl ether was slowly added to the mixture and stirred for 1 hour. Finally, after filtering the mixture through a silica filter, the filtrate was recrystallized to obtain the monomer (A-1) (22,6-dibromo-N-(4-hexyl phenyl)-4H-cyclopenta [2,1-b:3,4-b′] dithiophen-4-imine), which is a product according to Reaction 3, (yield: 73%).

### Synthesis Example 2: Synthesis of Monomer (B-1)

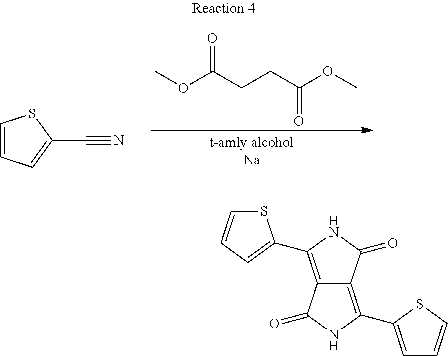

Metallic sodium (3.85 g) was gradually added to tert-amyl alcohol (244 mmol), followed by stirring at 120° C. overnight. After injecting thiophene-2-carbonitrile (204 mmol), a dimethyl succinate solution (0.67 M) in which dimethyl succinate (54 mmol) was dissolved in tert-amyl alcohol (80 mL) was injected. The dimethyl succinate solution was completely added, and the reaction mixture was then refluxed overnight. The reaction mixture was then cooled to 60° C., and then the reaction was quenched with 40 mL of acetic acid (99.5%). After filtering the sample through a reduced pressure filter, the filtrate was washed three times with hot methanol and water at 60°° C., and the resultant solid was then dried in a vacuum to obtain an intermediate compound (c) (3,6-di(thiophene-2-nyl)-2,5-dihydropyrrolo[3,4-c]pyrrole-1,4-dioene), which is a product according to Reaction 4, (yield: 78%).

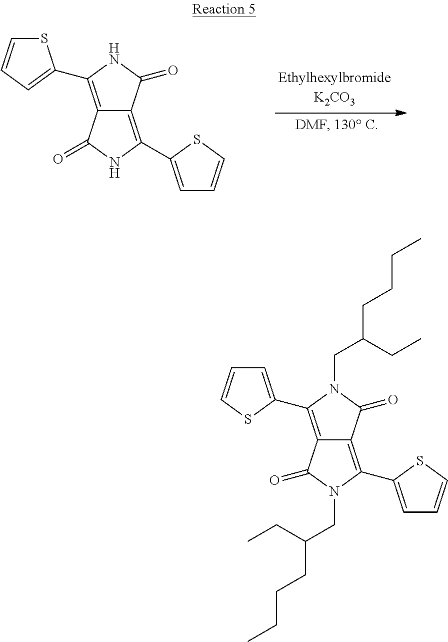 [SMILES: O=C1NC(c2cccs2)=C2C(=O)NC(c3cccs3)=C12 ; CCCCC(CC)CN1C(=O)C2=C(c3cccs3)N(CC(CC)CCCC)C(=O)C2=C1c1cccs1]

The intermediate compound (c) (0.35 g, 1.16 mmol) and anhydrous K₂CO₃ (1 g, 5.83 mmol) were dissolved in an anhydrous 15 mL of DMF in a nitrogen atmosphere, and then the resultant mixture was stirred for 1 hour at 130° C. Then, 2-ethylhexyl bromide (0.56 g, 3 mmol) was added to the mixture solution, and the resultant mixture was stirred at 130° C. for 24 hours. After extracting a sample with chloroform using a separatory funnel, moisture was removed by using MgSO₄, and the resultant was subjected to filtration under reduced pressure. The filtrate was purified by column chromatography (dichloromethane:hexane=2:1) to obtain an intermediate compound (d) (2,5-bis(2-ethylhexyl)-3,6-di(thiophen-2-yl)-2,5-dihydropyrrolo[3,4-c]pyrrole-1,4-dione), which is a product according to Reaction 5, (yield: 78%).

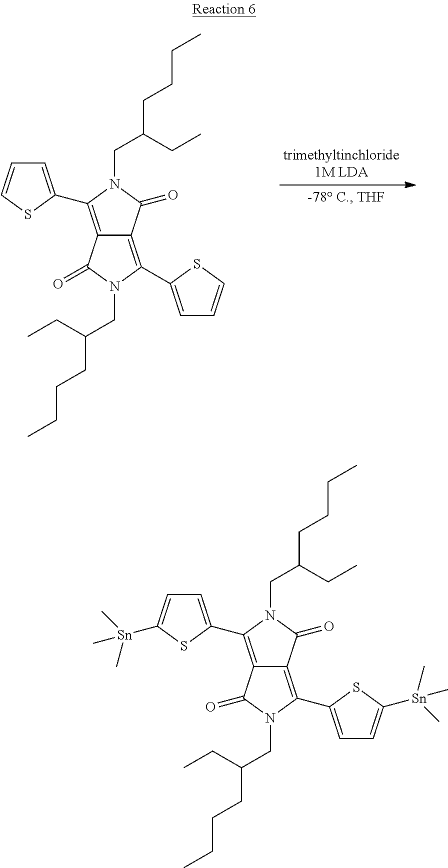

The intermediate compound (d) (0.37 g, 0.70 mmol) was dissolved in 15 mL of anhydrous THF within a 50 mL flask, and then the temperature was lowered to −78° C. in a nitrogen condition. 1M of LDA (5.6 mL, 5.6 mmol) was slowly injected to the mixture at −78° C., and then a reaction was allowed for 1 hour. Then, 1M Me₃SnCl (8.4 mL, 8.4 mmol) was slowly added to the mixture solution, followed by stirring overnight at room temperature. After extracting a sample with diethyl ether using a separatory funnel, moisture was removed from the sample using MgSO₄, and the resultant was subjected to filtration under reduced pressure. The filtrate was then recrystallized to obtain a monomer (B-1) (2,5-bis (2-ethylhexyl)-3,6-bis (5-(trimethylstenyl) thiophen-2-yl)-2,5-dihydropyrrolo [3,4-c] pyrrole-1,4-dioene), which is a product according to Reaction 6, (yield: 55%).

### Synthesis Example 3: Synthesis of Polymer (C-1)

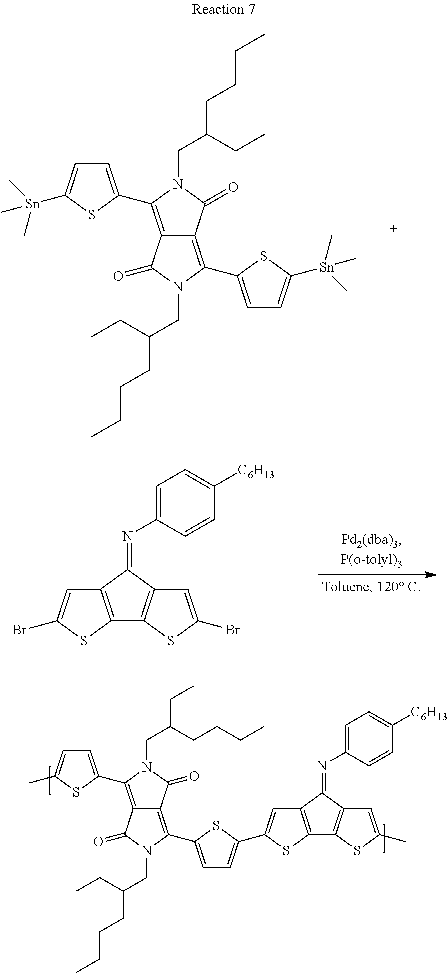

A monomer (A-1) (0.127 g, 0.25 mmol), a monomer (B-1) (0.212 g, 0.25 mmol), Pd₂ (dba)₃ (15 mg), and P(o-tol)₃ (20 mg) were added to 7 mL of toluene within a 50 mL two-necked flask in a nitrogen atmosphere and refluxed for 48 hours. The produced polymer was precipitated with methanol and then the resultant was purified by the Soxhlet extraction method using acetone and chloroform to obtain a polymer (C-1) (diketopyrrolopyrrol cyclopentadithiophene, PCPDTDPP), which is a product according to Reaction 7, ((120 mg, weight average molecular weight: 6.3 kDa, PDI: 1.5).

### EXAMPLE

### (1) Preparing of BHJ Film

The mixture solution formed by mixing with the ingredients in amounts listed in Table 1 below and stirring for 2 hours or more was spin-coated on a substrate to obtain BHJ film having a thickness of 10 nm.

TABLE 1

| | Mixture solution | | | | | | |
|---|---|---|---|---|---|---|---|
| | | | Light-absorbing | | | | |
| | Donor material | | material | | Acceptor material | | Solvent |
| | | Amount | | Amout | | Amout | (chloroform) |
| Classification | Types | (mg) | Types | (mg) | Types | (mg) | (mL) |
| Example 1 | PCPDTDPP | 10 | BDN | 10 | PC₇₀BM | 10 | 1 |
| Comparative | PCPDTDPP | 10 | — | — | PC₇₀BM | 10 | 1 |
| Example 1 | | | | | | | |
| Comparative | — | — | BDN | 10 | PC₇₀BM | 10 | 1 |
| Example 2 | | | | | | | |
| Comparative | P3HT | 10 | BDN | 10 | PC₇₀BM | 10 | 1 |
| Example 3 | | | | | | | |

In Table 1, PCPDTDPP is a polymer prepared in Synthesis Example 3, poly(3-hexylthiophene) (PH3T, made by EMNI Co., ltd) is a compound represented by Formula 6 below, BDN (made by TCI Co., ltd) is a compound represented by Formula 2-1 below, and PC₇₀BM (made by EMNI Co., ltd) is a compound represented by Formula 5-1 below.

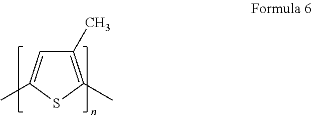

### (2) Preparing of Photoelectric Conversion Device

### Preparation Example: Preparing of a Photoelectric Conversion Device (D-1)

A glass substrate on which 300 nm of ITO was grown was washed by using toluene, acetone, and isopropyl alcohol (IPA), a mixture solution prepared by mixing 1 mL of diethyl zinc solution and 2 mL of tetrahydrofuran (THF) was spin-coated on ITO to form a ZnO film having a thickness of 40 nm on ITO.

10 mg of the polymer (C-1) (PCPDTDPP) powder, 10 mg of BDN powder, and 10 mg of PC₇₀BM powder were mixed in 1 mL of chloroform at a ratio of 1:1:1, and then stirred for 2 hours or more to prepare a PCPDTDPP:BDN: PC70BM solution. Thereafter, the first solution was spin-coated on the ZnO film to form a PCPDTDPP:BDN: PC70BM mixed film having a thickness of 100 nm.

A MoO₃ film having a thickness of 4 nm was formed by using the thermal evaporation method on the PCPDTDPP:BDN: PC70BM mixed film. Thereafter, an Au film having a thickness of 20 nm was formed on the MoO₃ film by using the thermal evaporation method to prepare a photoelectric conversion device (D-1). MoO₃ and Au were formed in a shape exposing the PCPDTDPP:BDN: PC70BM mixed film by using a shadow mask.

The photoelectric conversion device (D-1) according to Preparation Example 1 has a structure as followed.

Glass substrate/ITO (300 nm)/ZnO (40 nm)/PCPDTDPP:BDN: PC70BM (100 nm)/MoO₃(4 nm)/Au(20 nm)

Herein, ITO functions as a lower electrode, ZnO functions as an electron transport layer, PCPDTDPP:BDN: PC70BM functions as an active layer, MnO₃ functions as a hole transport layer, and Au functions as an upper electrode.

### EXPERIMENTAL EXAMPLE

### (1) Optical Characteristics of BHJ Film

UV-vis spectra (Jasco V-770) of BHJ films according to Example 1, and Comparative Examples 1 to 3 were measured.

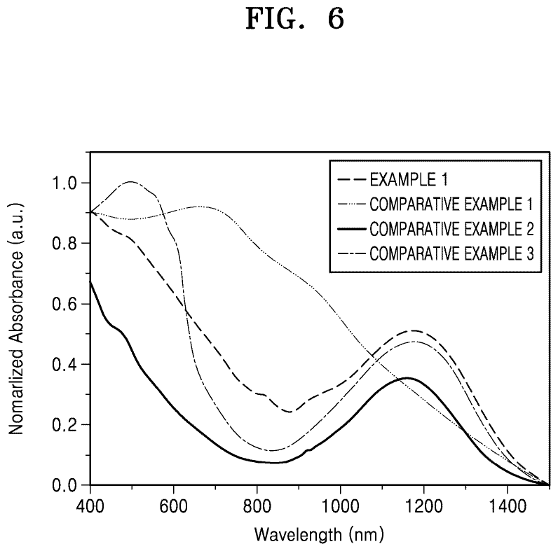

FIG. 6 shows light absorption spectra of the BHJ films according to Example 1, and Comparative Examples 1 to 3. Referring to FIG. 6, BHJ films according to Example 1, and Comparative Examples 2 and 3 had a peak wavelength in a range of about or exactly 1100 nm to about or exactly 1300 nm, but the BHJ film according to Comparative Example did not exhibit a peak wavelength in the range of about or exactly 1100 nm to about or exactly 1300 nm. It can be seen that the BHJ film according to Example 1, from a relative perspective, exhibited higher absorbance in the range of about or exactly 1100 nm to about or exactly 1300 nm than the BHJ films according to Comparative Examples 1 to 3, and thus was more advantageous for short wave infrared (SWIR) absorption.

### (2) Measuring Voltage-Photocurrent of Photoelectric Conversion Device

A light source emitting 1300 nm light at an intensity of 5 μW cm⁻² was sequentially turned on and off to measure photosensitivity on the photoelectric conversion device (D-1) according to Preparation Example 1.

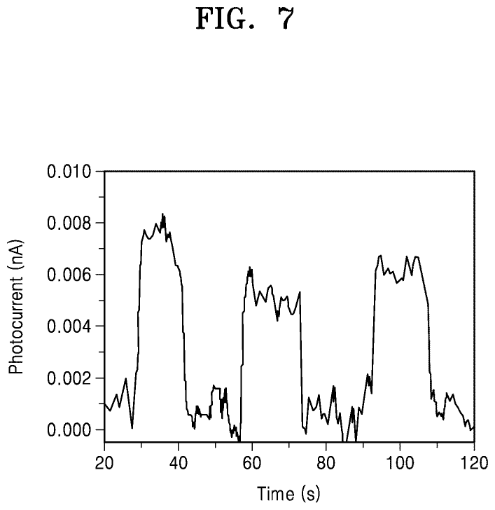

FIG. 7 is a time-photocurrent graph for the 1300 nm light at the intensity of 5 μW cm⁻² of the photoelectric conversion device (D-1) according to Preparation Example 1. Referring to FIG. 7, it can be seen that the photocurrent is generated by light in SWIR region.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hitherto, some example embodiments have been described with reference to the figures and Examples. Although the example embodiments have been described using specific terms in this specification, they are only used for the purpose of explaining the technical ideas of the present disclosure and are not used to limit the scope of the present disclosure described in the claims. It should be understood that various changes, modifications, and other equivalent embodiments can be made by one ordinary skilled in the art. Therefore, the true technical protection scope of the present disclosure should be determined by the technical spirit of the following claims.

While the inventive concepts have been particularly shown and described with reference to example embodiments thereof, it will be understood that various changes in form and details may be made therein without departing from the spirit and scope of the following claims.

What is claimed is:

1. A photoelectric conversion device comprising:
an upper electrode;
a lower electrode; and
an active layer including a donor material, an acceptor material, and a light-absorbing material, the active layer between the upper electrode and the lower electrode,
wherein the light-absorbing material includes bis-(4-dimethylaminodithiobenzyl)-Ni(II) (BDN), and the donor material includes a compound represented by Formula 1 below: 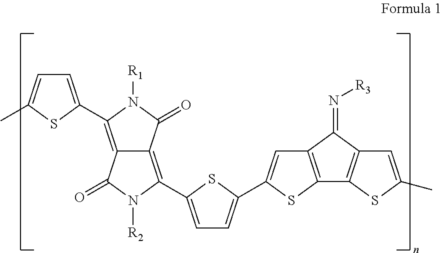
wherein in Formula 1, R₁ and R₂ are each independently a hydrogen atom, a C1 to C30 linear alkyl group that is unsubstituted or substituted with a substituent, or a C3 to C20 branched alkyl group that is unsubstituted or substituted with a substituent, R₃ is a hydrogen atom, a C6 to C30 aryl group that is unsubstituted or substituted with a substituent, or a C3 to C30 heteroaryl group that is unsubstituted or substituted with a substituent, and n is an integer between 20 and 100,000.

2. The photoelectric conversion device of claim 1, wherein an absolute value of a difference between a highest occupied molecular orbital (HOMO) energy level of the donor material and a HOMO energy level of the light-absorbing material is 0.3 eV or less.

3. The photoelectric conversion device of claim 1, wherein a HOMO energy level of the donor material is −5.1 eV or more, and a HOMO energy level of the light-absorbing material is −5.2 eV or more.

4. The photoelectric conversion device of claim 1, wherein a HOMO energy level of the donor material is less than a HOMO energy level of the light-absorbing material.

5. The photoelectric conversion device of claim 1, wherein a band gap energy of the donor material is 1.5 eV or less.

6. The photoelectric conversion device of claim 1, wherein a light absorption spectrum of the active layer has a peak wavelength in a range of 1 μm to 1.4 μm.

7. The photoelectric conversion device of claim 1, wherein the acceptor material includes [6,6]-Phenyl-C71-butyric acid methyl ester (PC₇₀BM).

8. The photoelectric conversion device of claim 1, wherein t
he donor material is included in an amount of 10 parts by weight to 80 parts by weight with respect to a total weight of the active layer,
the light-absorbing material is included in an amount of 10 parts by weight to 80 parts by weight with respect to the total weight of the active layer, and
the acceptor material is included in an amount of 10 parts by weight to 80 parts by weight with respect to the total weight of the active layer.

9. The photoelectric conversion device of claim 1, wherein the donor material includes a compound represented by Formula 1-1, below: 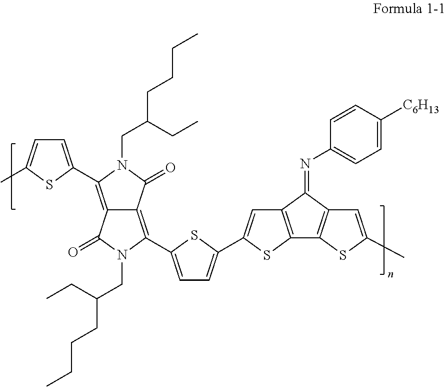
wherein in Formula 1-1, n is an integer between 20 and 100,000.

10. The photoelectric conversion device of claim 1, further comprising:
a lower transport layer between the active layer and the lower electrode; and
an upper transport layer between the active layer and the upper electrode.

11. A photoelectric conversion device comprising:
an upper electrode;
a lower electrode; and
an active layer including a donor material, an acceptor material, and a light-absorbing material, the active layer between the upper electrode and the lower electrode,
wherein an absolute value of a difference between a HOMO energy level of the donor material and a HOMO energy level of the light-absorbing material is 0.2 eV or less, and
wherein the light-absorbing material includes a compound represented by Formula 2-1, below:

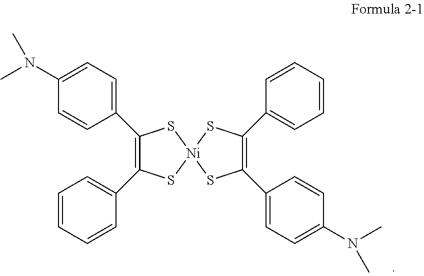

12. The photoelectric conversion device of claim 11, wherein the acceptor material includes [6,6]-phenyl-C71-butyric acid methyl ester (PC₇₀BM), [6,6]-phenyl-C61-butyric acid methyl ester (PC₆₀BM), bis(1-[3-(methoxycarbonyl)propyl]-1-phenyl)-[6,6]C62 (Bis-PCBM), poly{[N,N-bis(2-octyldodecyl)-naphthalene-1,4,5,8-bis(dicarboximide)-2,6-diyl]-alt-5,5-(2,29-bisthiophene)} (N2200), perylene diimide (PDI), or naphthalene diimide (NDI).

13. The photoelectric conversion device of claim 11, wherein
a HOMO energy level of the donor material is −5.0 eV or more, and
a band gap energy of the donor material is 1.5 eV or less.

14. The photoelectric conversion device of claim 11, wherein the donor material includes a compound represented by Formula 1, below: 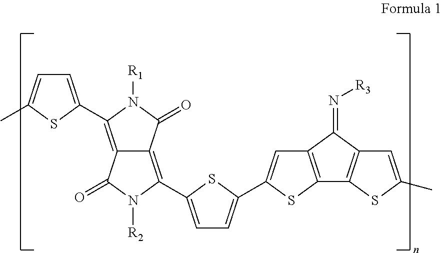
wherein in Formula 1, R₁ and R₂ are each independently a hydrogen atom, a C1 to C30 linear alkyl group that is unsubstituted or substituted with a substituent, or a C3 to C20 branched alkyl group that is unsubstituted or substituted with a substituent, R₃ is a hydrogen atom, a C6 to C30 aryl group that is unsubstituted or substituted with a substituent, or a C3 to C30 heteroaryl group that is unsubstituted or substituted with a substituent, and n is an integer between 20 and 100,000.

15. The photoelectric conversion device of claim 11, wherein the donor material includes a compound represented by Formula 1-1, below: 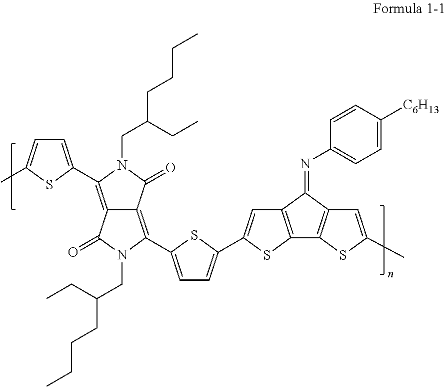
wherein in Formula 1-1, n is an integer between 20 and 100,000.

16. The photoelectric conversion device of claim 11, wherein, in the active layer, a ratio of an amount of the light-absorbing material to an amount of the donor material is 2:8 to 8:2.

17. An image sensor including the photoelectric conversion device according to claim 11.

18. An image sensor comprising:
a semiconductor substrate;
a charge storage in the semiconductor substrate;
an insulating layer on the semiconductor substrate;
a photoelectric conversion device on the insulating layer; and
a wiring connecting between the photoelectric conversion device and the charge storage,
wherein the photoelectric conversion device includes
a lower electrode connected to the wiring,
an active layer on the lower electrode, the active layer including a donor material, an acceptor material, and a light-absorbing material, and
an upper electrode on the active layer,
the donor material including a compound represented by Formula 1 below, and the light-absorbing material includes a compound represented by Formula 2-1 below: 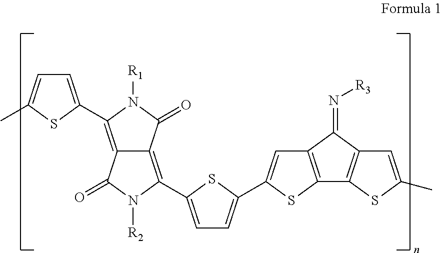
wherein in Formula 1, R₁ and R₂ are each independently a hydrogen atom, a C1 to C30 linear alkyl group that is unsubstituted or substituted with a substituent, or a C3 to C20 branched alkyl group that is unsubstituted or substituted with a substituent, R₃ is a hydrogen atom, a C6 to C30 aryl group that is unsubstituted or substituted with a substituent, or a C3 to C30 heteroaryl group that is unsubstituted or substituted with a substituent, and n is an integer between 20 and 100,000, and

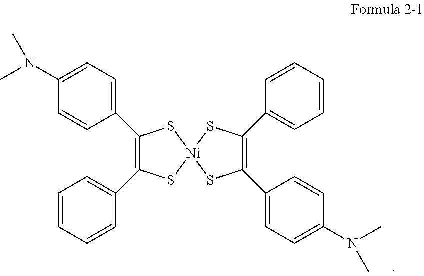

19. The image sensor of claim 18, wherein a HOMO energy level of the donor material is −5.0 eV or more.

20. The image sensor of claim 18, wherein a band gap energy of the donor material is 1.5 eV or less.
